(19) United States
(12) Patent Application Publication
(10) Pub. No.: US 2006/0199343 A1
(43) Pub. Date: Sep. 7, 2006

(54) Method of forming MOS transistor having fully silicided metal gate electrode

(76) Inventors: Sug-Woo Jung, Gyeonggi-do (KR); Gil-Heyun Choi, Gyeonggi-do (KR); Jong-Ho Yun, Gyeonggi-do (KR); Hyun-Su Kim, Gyeonggi-do (KR); Eun-Ji Jung, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/346,607

(22) Filed: Feb. 1, 2006

(30) Foreign Application Priority Data
Feb. 1, 2005 (KR) 2005-09258

(51) Int. Cl. H01L 21/336

(52) U.S. Cl. 438/294

(57) ABSTRACT

A method of fabricating a MOS transistor having a fully silicided metal gate electrode is provided. The method includes forming a gate sacrificial pattern and protrusion regions on the gate pattern and active regions of a semiconductor substrate. The gate sacrificial pattern and the protrusion regions then undergo a silicidation process. A reduced gate pattern is formed by disposing an interlayer-insulating layer on semiconductor substrate having the silicided gate sacrificial pattern and silicided protrusion regions, and planarizing the interlayer-insulating layer. The fully silicided metal gate electrode is then formed by siliciding the reduced gate pattern.

### CROSS-REFERENCE TO RELATED APPLICATION

This application claims the benefit of Korean Patent Application No. 10-2005-0009258, filed Feb. 1, 2005, the disclosure of which is hereby incorporated herein by reference in its entirety.

### BACKGROUND OF THE INVENTION

1. Field of the Invention

The present invention relates to a method of fabricating a semiconductor device, and more particularly, to a method of fabricating a Metal Oxide Semiconductor (MOS) transistor having a fully silicided metal gate electrode.

2. Description of the Related Art

In order to continue making advances in electronic products employing semiconductor devices, improvements in integration density, operating speed, and power consumption are required. Discrete devices such as MOS transistors are widely employed as switching devices for semiconductor devices. To meet the requirement of high integration, gates, source and drain junctions, and interconnections of the transistor should be reduced in size as much as possible. In addition, connections between the transistors should also be reduced in size.

However, transistor size reduction has several associated difficulties. For example, electrical resistance of the gate electrode increases as its size is reduced. In this case, an electrical signal applied to the gate electrode is delayed by a Resistance-Capacitance (RC) delay time. In addition, a short channel effect occurs due to the reduction of the channel length.

In the conventional art of employing polysilicon for the gate electrode, reduction of the size of the gate electrode further causes problems such as polysilicon depletion and boron penetration. Here, polysilicon depletion occurs in a depletion region adjacent to a gate insulating layer, i.e., a lower region within the polysilicon gate electrode. The polysilicon depletion region acts as an additional capacitance connected in series to the capacitance of the gate insulating layer. Consequently, the polysilicon depletion region causes the electrical equivalent thickness of the gate insulating layer to increase, which means a decrease in an effective gate voltage. In the conventional art, employing a thick gate insulating layer has a negligible effect since the thickness of the polysilicon depletion region is very small compared to the effective thickness of the thick gate insulating layer. However, as thinner gate insulating layers are used, the decrease in the effective gate voltage due to the polysilicon depletion region causes serious problems.

There are several advantages when a metal is used for the gate of the transistor instead of polysilicon. For example, the metal has a very high conductivity and may prevent gate depletion and boron penetration. However, the metal gate causes degradation of the gate insulating layer from metal ions and has a fixed work function, which makes it difficult to adjust a threshold voltage Vth. For example, a semiconductor device such as a complementary MOS (CMOS) transistor has an NMOS transistor region and a PMOS transistor region within a single chip. Threshold voltages of the NMOS and PMOS transistors should be adjusted to be different from each other. Consequently, a metal gate employed for the NMOS transistor region should be different from that employed for the PMOS transistor region, which makes the process very complicated.

To implement a high-performance MOS transistor suitable for a highly integrated semiconductor device, research into self-aligned silicide (i.e., salicide) technology has been done. Salicide technology is process technology for forming a metal silicide layer on the gate electrode and the source and drain regions to reduce their electrical resistance. In this case, a metal gate may be formed when the gate electrode is fully transformed into a metal silicide. In addition, when the gate electrode is transformed into the metal silicide in an N-doped or a P-doped state, a work function required from the NMOS or the PMOS can be obtained.

FIGS. 1 and 2 are cross-sectional views illustrating problems in a method of fabricating a metal gate electrode using the conventional silicide.

Referring to FIG. 1, an isolation layer 13 is formed to define an active region within the semiconductor substrate 11. A gate dielectric layer 17 and a gate electrode 19 are formed across the active region and are sequentially stacked. The gate electrode 19 is usually formed of a polysilicon layer. The gate electrode 19 is used as an ion implantation mask to form low concentration impurity regions 15 within the active region. Spacers 21 are formed on the side walls of the gate electrode 19. The gate electrode 19 and the spacers 21 are used as ion implantation masks to form source and drain regions 23 within the active region. Consequently, the low concentration impurity regions 15 may remain below the spacers 21. Subsequently, a metal layer 25 is formed to cover the entire surface of the semiconductor substrate 11 having the gate electrode 19 and the spacers 21.

Referring to FIG. 2, a silicidation process is carried out on the semiconductor substrate 11 having the metal layer 25. The metal layer 25 unreacted on the spacers 21 and the isolation layer 13 is then removed.

Consequently, the gate electrode 19 becomes silicided downward from the top so that a metal gate electrode 27 is formed. While the metal gate electrode 27 is formed, the source and drain regions 23 are also silicided downward from the top so that source and drain silicide layers 29 are formed. In this case, when the source and drain silicide layers 29 are deeper than a junction depth of the source and drain regions 23, leakage current occurs. That is, the source and drain silicide layers 29 must be formed to be shallower than the junction depth of the source and drain regions 23. Consequently, the metal gate electrode 27 is formed only on an upper region of the gate electrode 19.

A method of forming a metal gate electrode for improving the above-described problems is disclosed in U.S. Pat. No. 6,599,831 B 1 entitled “Metal Gate Electrode Using Silicidation and Method of Formation Thereof” to Maszara, et al.

According to Maszara, et al., a gate electrode and a capping layer are sequentially stacked on a predetermined region of a semiconductor substrate. A gate dielectric layer is interposed between the gate electrode and the semiconductor substrate. The gate electrode is formed of doped polysilicon. Spacers are then formed to cover sidewalls of the gate dielectric layer, the gate electrode, and the capping layer. Source and drain regions are formed in active regions of the semiconductor substrate using the capping layer and the spacers as ion implantation masks. The capping layer is selectively etched to expose the gate electrode. Subsequently, a metal layer covering the gate electrode and the source and drain regions is formed, and a silicidation process is carried out.

However, to prevent the spacers from being damaged while the capping layer is etched, the capping layer should be formed of a material having a high etch selectivity with respect to the spacers, but even so, it is not easy to remove the capping layer. For example, when the capping layer is an oxide layer, a trench isolation layer to be simultaneously exposed may be damaged. Alternatively, when the capping layer is a nitride layer, a trench liner to be simultaneously exposed may be damaged.

In addition, when the capping layer is not completely removed, the gate electrode cannot be fully transformed into silicide.

Consequently, a technique of completely transforming the gate electrode into silicide while preventing formation of a deep silicide layer in the source and drain regions is required.

### SUMMARY

Embodiments of the invention provide a method of fabricating a MOS transistor capable of preventing a deep silicide layer from being formed in source and drain regions while a gate electrode is fully transformed to a silicide.

One embodiment of the invention is directed to a method of fabricating a MOS transistor having a fully silicided metal gate electrode. The method includes forming an isolation layer defining an active region in a semiconductor substrate. An insulated gate pattern crossing over the active region is formed. Spacers are formed on sidewalls of the gate pattern. A selective epitaxial growth process is carried out on the gate pattern and the active regions on both sides of the gate pattern to form source and drain protrusion regions and a gate sacrificial pattern. A silicidation process is applied to the semiconductor substrate having the source and drain protrusion regions and the gate sacrificial pattern to form elevated source and drain silicide layers and a silicide sacrificial pattern. An interlayer-insulating layer is formed on the entire surface of the semiconductor substrate having the elevated source and drain silicide layers and the silicide sacrificial pattern. The interlayer-insulating layer is planarized to form a reduced gate pattern. A silicidation process is applied to the semiconductor substrate having the reduced gate pattern to form a fully silicided metal gate electrode.

### BRIEF DESCRIPTION OF THE DRAWINGS

The foregoing and other objects, features and advantages of the invention will be apparent from the detailed description of embodiments of the invention, as illustrated in the accompanying drawing. The drawings, however, are not necessarily to scale; rather emphasis has been placed on illustrating the principles of the invention.

FIGS. 1 and 2 are cross-sectional views illustrating problems in a conventional method of fabricating a metal gate electrode using silicide.

FIGS. 3 to 10 are cross-sectional views illustrating a method of fabricating a MOS transistor having a fully silicided metal gate electrode in accordance with embodiments of the present invention.

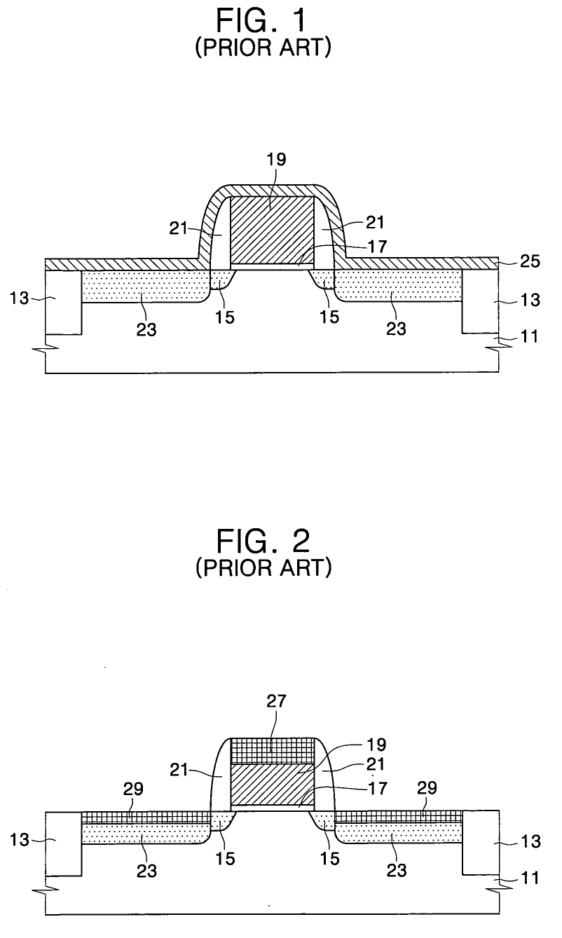

### DETAILED DESCRIPTION

The present invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. In addition, when a layer is described to be formed on another layer or on a substrate, the layer may be formed on the other layer or on the substrate, or one or more layers may be interposed between the layer and the other layer or the substrate. Like numbers refer to like elements throughout the specification.

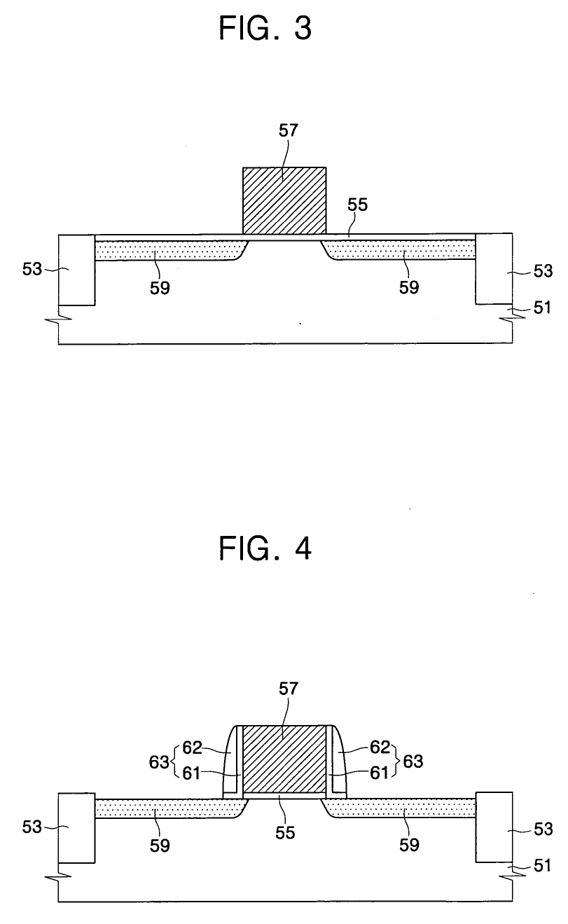

FIGS. 3 to 10 are cross-sectional views illustrating a method of fabricating a MOS transistor having a fully silicided metal gate electrode in accordance with some embodiments of the present invention.

Referring to FIG. 3, an isolation layer 53 is formed in a predetermined region of a semiconductor substrate 51 to define an active region. The semiconductor substrate 51 may be a silicon substrate. A gate dielectric layer 55 is formed on the active region. The gate dielectric layer 55 may be formed of a thermal oxide layer, e.g., a silicon oxide layer. A gate conductive layer is formed on the semiconductor substrate 51 having the gate dielectric layer 55. The gate conductive layer may be formed of a polycrystalline semiconductor layer such as a polysilicon layer doped with N-type impurities or P-type impurities.

The gate conductive layer is patterned to form a gate pattern 57 crossing over the active region. In this case, the process of forming the gate pattern 57 may include forming a hard mask pattern and a photoresist pattern sequentially stacked on the semiconductor substrate 51 having the gate conductive layer, and selectively etching the gate conductive layer, using the hard mask pattern and the photoresist pattern as etch masks. Subsequently, low concentration impurity ions are implanted into the active region, using the gate pattern 57 and the isolation layer 53 as ion implantation masks, to form lightly doped drain (LDD) regions 59. The low concentration impurity ions may be N-type impurity ions or P-type impurity ions.

Referring to FIG. 4, a spacer insulating layer is formed on the semiconductor substrate 51 having the LDD regions 59.

A cleaning process for removing surface-contaminated particles may be carried out on the semiconductor substrate 51 before the formation of the spacer insulating layer. The cleaning process may include a first cleaning step using a wet cleaning solution containing HF and a second cleaning step using a mixed solution of NH₄OH, H₂O₂, and H₂O. The exposed portion of the gate dielectric layer 55 may be etched and removed while the cleaning process is carried out. That is, the gate dielectric layer 55 may be present only under the gate pattern 57.

The spacer insulating layer may be formed of silicon oxide (SiO), silicon nitride (SiN), silicon oxynitride (SiON), or another similar material. The spacer insulating layer is anisotropically etched to form spacers 63 on the sidewalls of the gate pattern 57. For simplicity of description, it is hereinafter assumed that in this embodiment the spacer 63 is formed of a silicon oxide layer 61 and a silicon nitride layer 62 which are sequentially stacked. Consequently, the top surface of the gate pattern 57 is exposed, and the active regions on both sides of the gate pattern 57 are exposed.

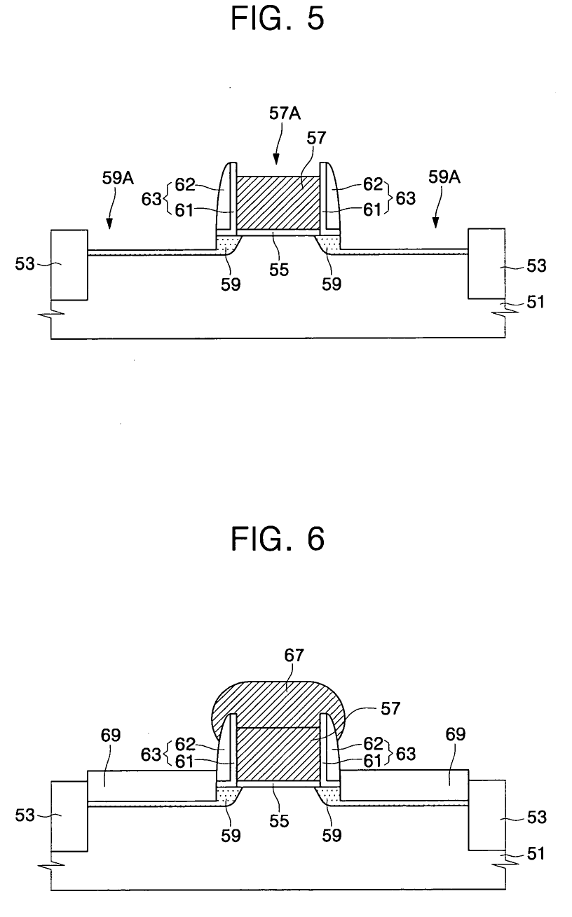

Referring to FIG. 5, the exposed active regions may be etched to form source and drain recess regions 59A. The top surface of the gate pattern 57 may also be etched to form a gate recess region 57A. Etching the exposed active regions may remove crystalline structure defects which may be formed within the exposed active regions. In this case, the etched depths of the source and drain recess regions 59A may be in a range of about 100 Å to about 1000 Å. In some embodiments, it may be preferable to restrict the range from about 100 Å to about 500 Å. The etched depth of the gate recess region 57A may be adjusted by an etch selectivity of the etching process. That is, the adjustment of the etch selectivity allows the gate pattern 57 to be etched faster or slower than the active regions. However, for this embodiment, it is assumed that the gate recess region 57A is formed to be shallower than the source and drain recess regions 59A.

In other embodiments, the process of forming the gate recess region 57A and the source and drain recess regions 59A may be skipped.

Referring to FIG. 6, a selective epitaxial growth (SEG) process is carried out on the semiconductor substrate 51 having the gate recess region 57A and the source and drain recess regions 59A to form a gate sacrificial pattern 67 and source and drain protrusion regions 69. In this case, a single crystalline semiconductor layer is grown in the source and drain recess regions 59A while a polycrystalline semiconductor layer is grown in the gate recess region 57A. The source and drain protrusion regions 69 are preferably protruded from a surface of the semiconductor substrate 51. That is, the top surfaces of the source and drain protrusion regions 69 are preferably higher than those of the gate dielectric layer 55. In addition, the gate sacrificial pattern 67 may be grown upward and laterally after it fills the gate recess region 57A, so that it can be shaped like a mushroom as shown in FIG. 6.

The gate sacrificial pattern 67 and the source and drain protrusion regions 69 may be formed of silicon (Si), silicon germanium compound (SiGe), silicon carbon compound (SiC), carbon (C) doped SiGe, phosphorus (P) doped SiGe, boron (B) doped SiGe, or another similar material.

Furthermore, the etching process and the SEG process may be repeated at least twice to form the gate sacrificial pattern 67 and the source and drain protrusion regions 69 to a desired thicknesses.

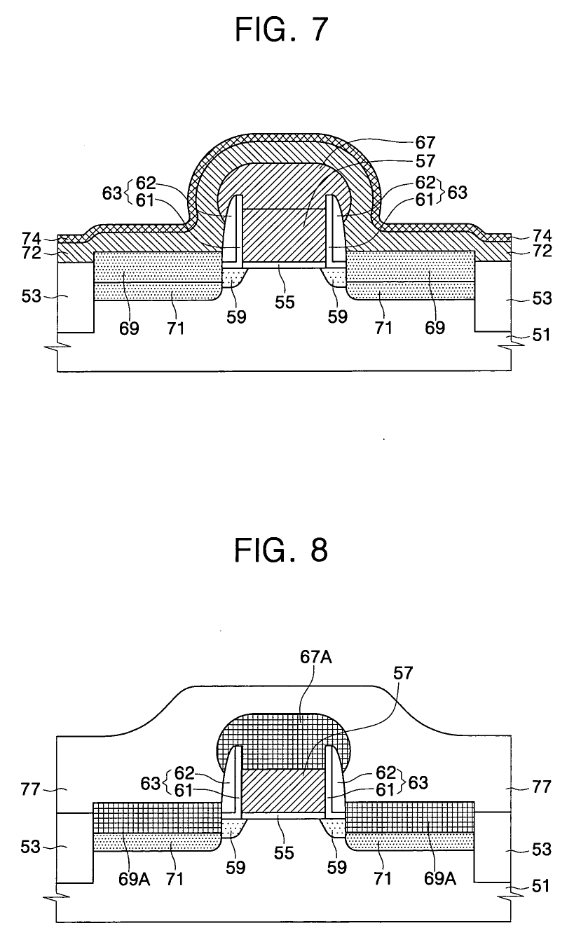

Referring to FIG. 7, high concentration impurity ions may be implanted into the source and drain protrusion regions 69 and the active region, using the gate sacrificial pattern 67, the spacer 63, and the isolation layer 53 as ion implantation masks, to form source and drain regions 71. As a result, the LDD regions 59 may remain below the spacer 63. The high concentration impurity ions may also be N-type impurity ions or P-type impurity ions, and the high concentration impurity ions and the low concentration impurity ions preferably have the same conductivity type. The process of implanting the high concentration impurity ions can use various energies and angles for implanting the ions. Alternatively, the process of implanting the high concentration impurity ions may be carried out, using the gate pattern 57, the spacer 63, and the isolation layer 53 as ion implantation masks, after the formation of the spacer 63. That is, the process of implanting the high concentration impurity ions may be carried out before the source and drain recess regions 59A are formed.

The surface of the semiconductor substrate 51 having the source and drain protrusion regions 69 is cleaned to remove a native oxide layer and contaminated particles remaining on the source and drain protrusion regions 69 and the gate sacrificial pattern 67. The cleaning process may include a first cleaning step using a wet cleaning solution containing HF and then a second cleaning step using a mixed solution of NH₄OH, H₂O₂, and H₂O.

A source and drain metal layer 72 and a capping layer 74 are sequentially formed on the entire surface of the cleaned semiconductor substrate 51. The source and drain metal layer 72 may be chosen from nickel (Ni), cobalt (Co), tungsten (W), tantalum (Ta), titanium (Ti), hafnium (Hf), nickel tantalum (NiTa), nickel platinum (NiPt), sequentially stacked nickel and cobalt (Ni/Co), and sequentially stacked PVD-Co/CVD-Co, or formed of at least two stacked layers thereof. The PVD-Co is cobalt (Co) formed by a physical vapor deposition (PVD) method, and the CVD-Co is cobalt (Co) formed by a chemical vapor deposition (CVD) method. The source and drain metal layer 72 may be formed by a PVD method, a CVD method, or an atomic layer deposition (ALD) method. In addition, the capping layer 74 may be formed of a titanium nitride (TiN) layer. In this case, the titanium nitride layer (TiN) acts to prevent the source and drain metal layer 72 from being oxidized. However, in other embodiments, the formation of the capping layer 74 may be skipped.

Referring to FIG. 8, a silicidation process is applied to the semiconductor substrate 51 having the source and drain metal layer 72. In particular, the silicidation process includes annealing the semiconductor substrate 51 having the source and drain metal layer 72 until the source and drain protrusion regions 69 are fully silicided to form elevated source and drain silicide layers 69A. For example, the annealing may be carried out at a temperature of about 400° C. to about 500° C. when the source and drain metal layer 72 is Ni. In addition, the annealing may be divided into a first annealing step and a second annealing step. During the annealing, the source and drain metal layer 72 reacts with silicon atoms within the gate sacrificial pattern 67 and the source and drain protrusion regions 69. Consequently, the gate sacrificial pattern 67 may also be silicided to form a silicide sacrificial pattern 67A.

The elevated source and drain silicide layers 69A may penetrate into partial regions of the source and drain regions 71. In this case, when the elevated source and drain silicide layers 69A are deeper than the junction depth of the source and drain regions 71, leakage current occurs. That is, it is preferable to form the elevated source and drain silicide layers 69A shallower than the junction depth of the source and drain regions 71. In addition, the silicide sacrificial pattern 67A may penetrate into a partial region of the gate pattern 57.

Subsequently, the unreacted portions of the source and drain metal layer 72 on the spacer 63 and the isolation layer 53 are removed. The unreacted source and drain metal layer 72 can be removed using a mixed solution of sulfuric acid (H₂SO₄) and hydrogen peroxide (H₂O₂). While the unreacted source and drain metal layer 72 is removed, the capping layer 74 may also be stripped.

An interlayer-insulating layer 77 is formed on the semiconductor substrate 51 having the elevated source and drain silicide layers 69A and the silicide sacrificial pattern 67A.

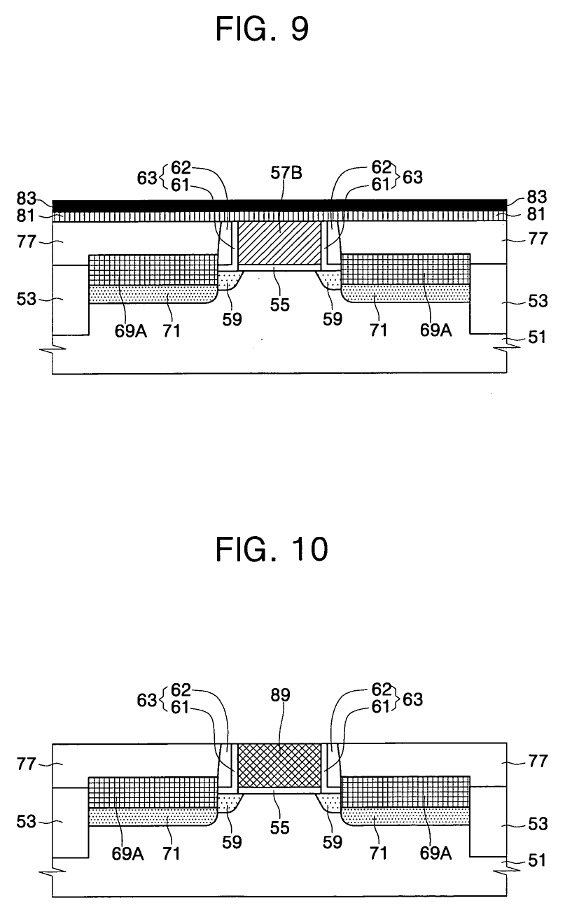

Referring to FIG. 9, the interlayer-insulating layer 77 is planarized to expose the gate pattern 57 and the spacer 63 using a conventional planarization process such as a chemical mechanical polishing (CMP) process. Consequently, the gate pattern 57 becomes less than its initial thickness so that a reduced gate pattern 57B is formed.

A gate metal layer 81 and a gate capping layer 83 covering the reduced gate pattern 57B are sequentially formed. The gate metal layer 81 may be chosen from Ni, Co, W, Ta, Ti, Hf, NiTa, NiPt, sequentially stacked nickel and cobalt (Ni/Co), and sequentially stacked PVD-Co/CVD-Co, or formed of at least two stacked layers thereof. The PVD-Co is Co formed by a PVD method, and the CVD-Co is Co formed by a CVD method, as mentioned above. The gate metal layer 81 may be formed by a PVD method, a CVD method, or an atomic layer deposition (ALD) method. In addition, the gate capping layer 83 may be formed of TiN. In this case, the titanium nitride (TiN) layer prevents the gate metal layer 81 from being oxidized. However, in other embodiments, the formation of the gate capping layer 83 may be skipped.

Referring to FIG. 10, a silicidation process is applied to the semiconductor substrate 51 having the gate metal layer 81. More specifically, the silicidation process includes annealing the semiconductor substrate 51 having the gate metal layer 81 until the reduced gate pattern 57B is fully silicided to form a fully-silicided metal gate electrode 89. For example, the annealing may be carried out at a temperature of about 400° C. to about 500° C. when the gate metal layer 81 is formed of Ni. In addition, the annealing may be divided into a first annealing step and a second annealing step. During the annealing, the gate metal layer 81 reacts with silicon atoms within the reduced gate pattern 57B. Consequently, the reduced gate pattern 57B may also be fully silicided to form the fully silicided metal gate electrode 89.

Subsequently, the unreacted portion of the gate metal layer 81 on the spacer 63 and the interlayer-insulating layer 77 is removed. The unreacted gate metal layer 81 can be removed using a mixed solution of H₂SO₄ and H₂O₂. While the unreacted gate metal layer 81 is removed, the gate capping layer 83 may also be stripped.

The source and drain metal layer 72 and the gate metal layer 81 may be formed of the same metal material or different metal materials from each other. When the source and drain metal layer 72 and the gate metal layer 81 are formed of different metal materials from each other, the elevated source and drain silicide layers 69A and the fully silicided metal gate electrode 89 may be formed of silicide layers of different metal materials from each other.

According to some embodiment of the present invention described above, after an elevated source and drain silicide layers and a silicide sacrificial pattern are formed using an SEG process and a silicidation process, a planarization process such as a CMP process is carried out to remove the silicide sacrificial pattern. A reduced gate pattern is exposed due to the removal of the silicide sacrificial pattern. The reduced gate pattern is transformed to a fully-silicided metal gate electrode using the silicidation process. Accordingly, the formation of deep silicide layers in source and drain regions can be prevented when forming a fully silicided metal gate electrode. That is, the elevated source and drain silicide layers can be formed in a region shallower than the junction depth of the source and drain. Consequently, a MOS transistor having a fully silicided metal gate electrode can be fabricated, which may have a higher integration density and better performance compared to conventional MOS transistors.

Embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a semiconductor device, comprising:
forming an isolation layer to define an active region in a semiconductor substrate;
forming an insulated gate pattern crossing over the active region;
forming spacers on sidewalls of the gate pattern;
forming a gate sacrificial pattern and source and drain protrusion regions on the gate pattern and the active regions on both sides of the gate pattern, respectively, using a selective epitaxial growth process;
applying a silicidation process to the semiconductor substrate having the source and drain protrusion regions and the gate sacrificial pattern to form elevated source and drain silicide layers and a silicide sacrificial pattern;
forming an interlayer-insulating layer on the semiconductor substrate having the elevated source and drain silicide layers and the silicide sacrificial pattern;
planarizing the interlayer-insulating layer to form a reduced gate pattern; and
applying a silicidation process to the semiconductor substrate having the reduced gate pattern to form a fully-silicided metal gate electrode.

2. The method according to claim 1, wherein the gate pattern is formed of a polycrystalline semiconductor layer.

3. The method according to claim 1, further comprising implanting low concentration impurity ions into the active region, using the gate pattern and the isolation layer as ion implantation masks, after forming the insulated gate pattern crossing over the active region, to form lightly doped drain (LDD) regions.

4. The method according to claim 1, wherein the spacer is formed of a material chosen from slicon oxide (SiO), silicon nitride (SiN), and silicon oxynitride (SiON).

5. The method according to claim 1, further comprising selectively etching the gate pattern and the active regions on both sides of the gate pattern before forming the source and drain protrusion regions and the gate sacrificial pattern, to form source and drain recess regions and a gate recess region.

6. The method according to claim 5, wherein each of the source and drain recess regions is formed to a depth of about 100 Å to about 1000 Å.

7. The method according to claim 1, wherein the source and drain protrusion regions are formed of single crystalline semiconductor layers, and the gate sacrificial pattern is formed of a polycrystalline semiconductor layer.

8. The method according to claim 1, wherein the source and drain protrusion regions and the gate sacrificial pattern are formed of a material chosen from silicon (Si), silicon germanium compound (SiGe), silicon carbon compound (SiC), carbon (C) doped SiGe, phosphorus (P) doped SiGe, and boron (B) doped SiGe.

9. The method according to claim 1, wherein the source and drain protrusion regions protrude from a surface of the semiconductor substrate.

10. The method according to claim 1, wherein the source and drain protrusion regions have top surfaces positioned higher than a gate dielectric layer.

11. The method according to claim 1, wherein the gate sacrificial pattern has a mushroom shape.

12. The method according to claim 1, wherein forming the elevated source and drain silicide layers and the silicide sacrificial pattern includes:
forming a source and drain metal layer on an exposed surface of the semiconductor substrate having the source and drain protrusion regions and the gate sacrificial pattern;
annealing the semiconductor substrate having the source and drain metal layer; and
removing unreacted portion of the source and drain metal layer on the spacer and the isolation layer.

13. The method according to claim 12, wherein the source and drain metal layer are formed of a material chosen from nickel (Ni), cobalt (Co), tungsten (W), tantalum (Ta), titanium (Ti), hafnium (Hf), nickel tantalum (NiTa), nickel platinum (NiPt), sequentially stacked nickel and cobalt (Ni/Co), and sequentially stacked Physical Vapor Deposition (PVD)-Co/Chemical Vapor Deposition (CVD)-Co, or formed of at least two stacked layers thereof.

14. The method according to claim 12, further comprising forming a capping layer on the source and drain metal layer.

15. The method according to claim 14, wherein the capping layer is formed of a titanium nitride (TiN) layer.

16. The method according to claim 1, wherein the planarization is performed using a chemical mechanical polishing (CMP) process.

17. The method according to claim 1, wherein forming the fully silicided metal gate electrode includes:
forming a gate metal layer on the reduced gate pattern and the interlayer-insulating layer;
annealing the semiconductor substrate having the gate metal layer; and
removing unreacted portion of the gate metal layer on the interlayer-insulating layer.

18. The method according to claim 17, wherein the gate metal layer is formed of a material chosen from Ni, Co, W, Ta, Ti, Hf, NiTa, NiPt, sequentially stacked nickel and cobalt (Ni/Co), and sequentially stacked PVD-Co/CVD-Co, or formed of at least two stacked layers thereof.

19. The method according to claim 17, further comprising forming a gate capping layer on the gate metal layer.

20. The method according to claim 19, wherein the gate capping layer is formed of a titanium nitride (TiN) layer.

21. The method according to claim 1, wherein the fully silicided metal gate electrode is formed of a silicide of the same metal material as the elevated source and drain silicide layers.

22. The method according to claim 1, wherein the fully silicided metal gate electrode is formed of a silicide layer of a metal material different from the elevated source and drain silicide layers.

23. A method of fabricating a metal oxide semiconductor (MOS) transistor, comprising:
forming an isolation layer defining an active region in a region of a semiconductor substrate;
forming an insulated gate pattern crossing over the active region;
forming spacers on sidewalls of the gate pattern;
selectively etching the gate pattern and the active regions on both sides of the gate pattern to form a gate recess region and source and drain recess regions, respectively;
forming a gate sacrificial pattern and source and drain protrusion regions on the gate recess region and the source and drain recess regions, respectively, using a selective epitaxial growth process;
applying a silicidation process to the semiconductor substrate having the source and drain protrusion regions and the gate sacrificial pattern to form elevated source and drain silicide layers and a silicide sacrificial pattern;
forming an interlayer-insulating layer on an exposed surface of the semiconductor substrate having the elevated source and drain silicide layers and the silicide sacrificial pattern;
planarizing the interlayer-insulating layer to form a reduced gate pattern; and
applying a silicidation process to the semiconductor substrate having the reduced gate pattern to form a fully-silicided metal gate electrode.

24. The method according to claim 23, wherein the gate sacrificial pattern has a mushroom shape.

25. The method according to claim 23, wherein the planarization comprises a chemical mechanical polishing (CMP) process.

26. The method according to claim 23, wherein the fully silicided metal gate electrode is formed of a silicide layer of the same metal material as the elevated source and drain silicide layers.

27. The method according to claim 23, wherein the fully silicided metal gate electrode is formed of a silicide layer of a metal material different from the elevated source and drain silicide layers.

28. A method of fabricating a semiconductor device, comprising:
providing a gate pattern on a semiconductor substrate having active regions defined therein;
forming a gate sacrificial pattern and protrusion regions on the gate pattern and the active regions on both sides of the gate pattern, respectively;
siliciding the gate sacrificial pattern and protrusion regions;
forming an interlayer-insulating layer on the resulting structure and planarizing the interlayer-insulating layer including the gate sacrificial pattern, thereby forming a reduced gate pattern; and
forming a fully silicided metal gate electrode by siliciding the reduced gate pattern.

29. The method according to claim 28, further comprising forming a gate recess region and source/drain recess regions by selectively etching the gate pattern and the active regions on both sides of the gate pattern before forming the gate sacrificial pattern and protrusion regions.

30. The method according to claim 28, wherein the protrusion regions are formed to protrude from a surface of the semiconductor device.

31. The method according to claim 28, wherein siliciding the gate sacrificial pattern and protrusion regions comprises:
forming a first metal layer on the semiconductor substrate structure;
annealing the semiconductor substrate structure; and
removing the unreacted portion of the first metal layer.

32. The method according to claim 31, further comprising forming a first capping layer on the first metal layer.

33. The method according to claim 28, wherein siliciding the reduced gate pattern comprises:
forming a second metal layer on the semiconductor substrate structure;
annealing the semiconductor substrate structure; and
removing the unreacted portion of the second metal layer.

34. The method according to claim 33, further comprising forming a second capping layer on the second metal layer.

35. The method according to claim 28, wherein the gate pattern includes spacers formed on sidewalls thereof, and wherein planarizing is performed until the gate pattern and the spacer are exposed.
